(19) United States
(12) Patent Application Publication
(10) Pub. No.: US 2026/0188382 A1
(43) Pub. Date: Jul. 2, 2026

(54) SENSING CIRCUIT AND SCHEME FOR READING FOUR-TRANSISTOR STATIC RANDOM ACCESS MEMORY

(71) Applicant: FlashSilicon Incorporation, Diamond Bar, CA (US)

(72) Inventors: Lee Wang, Diamond Bar, CA (US); Xiang Su, Hangzhou (CN); YanZhen Wang, Hangzhou (CN)

(21) Appl. No.: 19/024,974

(22) Filed: Jan. 16, 2025

(30) Foreign Application Priority Data
Dec. 26, 2024 (CN) 202411952209.8

(51) Int. Cl. G11C 11/419

(52) U.S. Cl. CPC G11C 11/419

(57) ABSTRACT

A memory device is disclosed, comprising a 4T-SRAM cell and a sensing circuit. The 4T-SRAM cell comprising two P-type MOSFET devices for a data bit storage and two N-type MOSFET devices for accessing switches has benefits of less numbers of MOSFET devices for smaller cell size and low leakage current. The sensing circuit comprises a switch device, a latch and a discharge device. The switch device coupled between the sensing latch and the ground voltage rail is designed to reduce the read disturbance to 4T SRAM cell from the sensing circuit by cutting the channel leakage current paths of NMOSFET transistors in the latch to the ground voltage rail. The differential voltage signals for the reading digital data stored in 4T SRAM cells are enhanced by increasing the sensing period. The read margins for 4T SRAM are then greatly improved leading to excellent reliable reading.

### CROSS-REFERENCE TO RELATED APPLICATIONS

This application claims priority of No. 202411952209.8 filed in China on Dec. 26, 2024 under 35 USC 119, the entire contents of which are hereby incorporated by reference.

### BACKGROUND OF THE INVENTION

### FIELD OF THE INVENTION

The invention relates to the sensing circuit and timing scheme for reading the bit information stored in Four-Transistor Static Random Access Memory (4T SRAM) cells. In particular, the new sensing circuit in conjunction with the sensing scheme reduces the sensing circuit read disturbance for the small differential bitline voltage signals generated from the storage nodes of a 4T SRAM cell in memory arrays. The read margins for 4T SRAM are also greatly improved by the new sensing circuit and timing scheme resulting in excellent read reliability.

### DESCRIPTION OF THE RELATED ART

Semiconductor memories have been broadly applied to electronic systems. Electronic systems require semiconductor memories for storing instructions and data from the basic functions of controls to the complex computing data processes. Semiconductor memories can be cataloged as volatile memories and non-volatile memories. The volatile memories including Static Random Access Memory (SRAM) and Dynamic Random Access Memory (DRAM) lose their stored data after the memory's powers off while the non-volatile memories such as Read Only Memory (ROM), Electrical Erasable Programmable Read Only Memory (EEPROM) and flash still keep their stored data even without the memory power.

Since computing processors run at very high frequency clock speeds (tens of MHz˜tens of GHz), the access times for reading data and altering data in memory have to be compatible with the computing speeds of computing processors. The volatile SRAM and DRAM are the memory of choices for computer processors due to their fast random memory access time for read/write operations. DRAM cell simply consisting of one MOSFET device for the access switch and one capacitor for a bit of storage can be fabricated with DRAM process technology to very high densities with very low fabrication cost. However, DRAM requires to constantly refresh leading to high power consumption. Since SRAM does not require data refresh the power consumption for SRAM is much less than those for DRAM. Furthermore, SRAM is fabricated with the CMOS (Complementary Metal Oxide Semiconductor) process technology, the same process technology for fabricating digital processor Integrated Circuits (IC). Therefore, SRAM is usually embedded with digital processor for the memory requirement in IC chips. However, since the conventional SRAM cell for one bit of storage comprises six MOSFET devices occupying much larger silicon area than the conventional DRAM cell (one MOSFET device and one capacitor), the per-bit-storage cost for SRAM is much higher than that for DRAM. Therefore, it is very desirable to reduce the cell sizes of SRAM by applying less numbers of MOSFET devices to improve the memory density and to lower the per-bit-storage cost for digital processor IC chips. As shown in FIG. 1 the conventional SRAM cell 100 includes six MOSFET devices: two N-type MOSFET devices 13, 14 for access switches and a cross-coupled inverter latch: (PMOSFET device 11 and NMOSFET device 15) and (PMOSFET device 12 and MOSFET device 16) for a bit of data storage, where the cross-coupled inverter latch forms the two storage nodes n1 and n2, respectively. As shown in FIG. 2, the 4T SRAM cell 200 includes four MOSFET devices: two N-type MOSFET devices 23, 24 for access switches and two cross-coupled P-type MOSFET devices 22, 21 for a bit of data storage, where the drain electrodes of the cross-coupled PMOSFET devices 21, 22 form the two storage nodes n3 and n4, respectively. For SRAM per-bit-storage cost reduction, the size of the 4T (four MOSFET devices) SRAM cell 200 in FIG. 2 is usually about 25%˜35% smaller than that of the conventional 6T SRAM cell 100 in FIG. 1 fabricated with the same CMOS fabrication process technology node. Although the 4T SRAM cell 200 can save per-bit-storage cost for less numbers of MOSFET devices, reliable reading the stored data from the 4T SRAM cells still remains the most critical issue for the broad application of 4T SRAM in IC chips.

A 4T SRAM cell 200 stores one bit of datum by setting asymmetrical voltage potentials such as V_{DD} (digital supply/high voltage) and V_{SS} (ground voltage) for data “1”, and V_{SS} and V_{DD} for datum “0” respectively at the cell's two storage nodes n3 and n4. The stored datum in the 4T SRAM cell 200 is then read back by sensing the asymmetrical voltage potentials at the SRAM cell's two storage nodes n3 and n4. For the 6T SRAM data storage, the cross-coupled inverter latch (inverter devices 12, 16 and inverter devices 11, 15) of the 6T SRAM cell 100 in FIG. 1 always keep one storage node connected to V_{DD} and the other storage node connected to V_{SS} after the datum has been stored in the 6T SRAM cell 100. It is straightforward to apply the conventional SRAM sensing circuit and scheme or more recent read-assist sensing circuit to read out the data from the conventional 6T SRAM cell 100. While writing datum into the 4T SRAM cell 200 in FIG. 2, the storage nodes n3 and n4 are initially set to the voltage potentials V_{DD} and V_{SS} for data “1”, and the voltage potentials V_{SS} and V_{DD} for “0”, respectively with the write circuit in U.S. patent application Ser. No. 18/418,060. However, after writing into the 4T SRAM cell 200 for the data retention period with the access transistors 23, 24 off, unlike the 6T SRAM cell 100, the voltage potential at one storage node in 4T SRAM cell 200 in FIG. 2 is always floating without connecting to the ground voltage V_{SS}. The voltage potential at the floating node will rise from the ground voltage to a steady voltage potential less than the digital supply/high voltage V_{DD} depending on the leakage current balance between the PMOSFET channel diffusion current and the accessing NMOSFET diode leakage current in the 4T SRAM cell 200 as disclosed in U.S. patent application Ser. No. 18/661,126.

To minimize the read error for the floating storage node in the 4T SRAM 200, the sensing circuit 350 in FIG. 3 in U.S. patent application Ser. No. 18/418,060 is designed to read datum from the rising floating voltage potential at one storage node n3/n4 and V_{DD} at the other storage node n4/n3 in the 4T SRAM cell 200 by (1) discharging any residual charges on the connecting bit-line BL 321 and complementary bit-line BL 322 by the two NMOSFET devices 311 prior to accessing a 4T SRAM cell 200 for avoiding the unwanted read interference, (2) sensing the differential voltage potential between the connecting bit-line BL 321 and the connecting complementary bit-line BL 322 passed from cell's two storage nodes n3 and n4, and (3) simultaneously refreshing the original data voltage potentials (V_{DD} and VSS) at the two storage nodes in the cell data read period/process. When the wordline 334 (gates of the cell's access MOSFET 24 and 23) of the selected 4T SRAM cell 200 is activated for the reading cell data process, the differential voltages between the bitline 321 and complementary bitline 322 attached to the sensing circuit 350 and passed from the cell's storage nodes n3 and n4 will be initially further reduced to a much smaller differential voltage signals by the initial inter-capacitance charge sharing effect between a small gate capacitance of cell's PMOSFET device and a large capacitance of the bitlines as the second row shown in FIG. 4. For example, for the capacitance of the bitline attached with 256 memory cells in a 4T SRAM memory array in one embodiment, the voltage potential at the high voltage storage node n3 for stored data “1” in the second row of FIG. 4 initially drops from 1.2 V to 175.6 mV, when the wordline voltage potential (the first row in FIG. 4) is turned on. Meanwhile during the bitline voltage dropping process, the voltage at the storage node n4 (connected to the gate of the PMOSFET device 22) also drops to compensate the complementary capacitance sharing effect and the voltage potential at the storage node n4 varies from the original 17.4 mV to 131.6 mV. The both initially “on” cell's PMOSFET devices 21 and 22 with gate voltage below the (V_{DD}—cell's PMOSFET threshold voltage (approximately 0.42 V)) start to respectively charge the capacitance 341 for bitline 321 and the capacitance 342 for the complementary bitline 322 to rise up the storage node voltage potentials and the bitline and complementary bitline voltage potentials as well shown in the second and the third row of FIG. 4, respectively. Meanwhile for the case of reading the 4T SRAM cell stored with data “1”, since the gate voltage potential (initially 175.6 mV) of PMOSFET 21 connected with storage node n3 is higher than the gate potential (initially 131.6 mV) of PMOSFET 22 connected with storage node n4, the voltage potential at bitline 321 faster charged by the PMOSFET device 22 to a voltage potential is supposedly to be higher than the voltage potential at the complementary bitline 322 slower charged by the PMOSFET device 21. However as illustrated in FIG. 4, for the error reading case for the stored data “1” 4T SRAM cell, the differential voltage potential ΔV between the bitline and the complementary bitline somehow evolves to the cross over voltage, i. e., equal bitline and complementary bitline voltage potential (i.e., ΔV=0 V), and to the opposite sign of the original differential voltage leading to the error bit reading and cell bit altering by the sensing circuit 350 shown in the second and third row in FIG. 4. The error reading events could be increased by marginal designs of the sensing circuit 350 and the sensing timing inaccuracy from a timing circuit resulting due to the MOSFET device variations in manufacturing process and different operational temperature environment. It is found that the channel leakage currents of NMOSFET devices 313 and 314 in the sensing circuit 350 are the responsible cause for the error reading events. In this invention we redesign the new sensing circuit 550 to cut the channel leakage current paths of NMOSFET 313 and 314 to prevent the sensing circuit read disturbance to 4T SRAM cells. With the new sensing circuit and timing sensing scheme, the read margin for 4T SRAM is thus enhanced to encounter the MOSFET device variations from the manufacturing process and different operational temperature for IC chips.

### SUMMARY OF THE INVENTION

Since the 4T-SRAM cell 200 does not have the low voltage node V_{SS} connected to the ground voltage as the conventional 6T-SRAM cell for being always biased with the ground voltage in one of the storage nodes_{,} one floating storage node n 4/n3 of the 4T-SRAM cell 200 is required to restore to the ground voltage in the cell data read process/period for retaining the original stored datum. The sensing circuit 550 is designed to have the capability to restore the ground voltage for the floating storage node of the selected 4T-SRAM cell in the cell data read process/period.

For the 4T-SRAM cell 200, since the voltage potential of the floating storage node is below the high voltage potential V_{DD} of the other storage node during the cell data retention period, a sensing circuit 550 is designed to detect the asymmetrical voltage difference (V_{DD}-V_{floating}) between two storage nodes of the selected 4T-SRAM cell 200 such that the full digital voltage signals, the high voltage V_{DD} and the ground voltage V_{SS}, can be obtained for the output signals during the cell data read process/period, where V_{floating} is the voltage potential of the floating storage node for the 4T-SRAM cell 200 during the data retention period as shown in FIG. 6. The floating storage node voltage potential V_{floating} is a voltage potential below the supply voltage V_{DD} and above the ground voltage. The steady-state floating storage node voltage potential V_{floating} for a 4T-SRAM cell (for example, see the curve 605 in FIG. 6) can be obtained for the detailed balanced leakage currents between the PMOSFET device 21/22 channel diffusion current (V_{DD} to the steady V_{floating}) with the reversed P-drain/N-well junction leakage current (V_{DD} to the steady V_{floating}) and the reversed N-drain/P-substrate junction leakage current of the access NMOSFET device 23/24 (the steady V_{floating} to substrate). In general, the higher reversed N-drain/P-substrate junction leakage current of the access NMOSFET device 23/24, the lower steady floating storage node voltage potential toward the ground voltage can be obtained.

The schematic of the sensing circuit 550 for reading the 4T SRAM cell 200 according to the invention is shown in FIG. 5. The sensing circuit 5 50 of the invention comprises two bitline reset NMOSFET devices 311 for discharging residual charges on the bitline BL 321 with loading capacitance C_{BL} 341 and the complementary bitline B̅L̅ 322 with loading capacitance C_{BL} 342, the send enabled PMOSFET device 312, the two sensing cross-connected inverters 5a and 5b, the tri-state buffer 315 and an NMOSFET device 516 for cutting the sensing circuit leakage current paths to the ground potential. The NMOSFET device 516 with its gate electrode connected to a sensing voltage signal “Sn” is coupled between the source electrodes (node 57) of NMOSFET devices 313 and 314, and the ground voltage potential shown in FIG. 5. The NMOSFET device 516 is used to cut the channel leakage current paths of NMOSFET 313 and 314 to prevent the sensing circuit read disturbance to 4T SRAM cells. The read sequence for reading the 4T SRAM cell 200 starts with

resetting the bitline BL 321 and the complementary bitline B̅L̅ 322 to ground potential by applying a voltage pulse signal BLrst V_{DD} at node 331 for a time τ as shown the first row in FIG. 6. After discharging bitline 321 and complementary bitline 322 for the time period τ, the selected wordline is turned on with the voltage signal V_{DD} at node 534 (the third row of FIG. 6) in the 4T SRAM memory array. When the selected wordline is turned “on”, the voltage potentials at storage nodes n3 and n4 of the selected 4T SRAM cell 200 are both initially dropped to the voltage potentials close to the ground voltage due to the bitline capacitance and complementary bitline capacitance charge sharing with the cell PMOSFET's gate capacitance at the storage nodes n3 and n4, approximately given by V_{b}≅(V_{DD}×(C_{pg}/(C_{pg}+C_{bL}))) and V_{cb}≅(V_{floating}×(C_{pg} / (C_{pg}+C_{bL}))) shown in the fourth row of FIG. 6 for stored cell data “1” and vice versa for the stored data “0”, where V_{b} and V_{cb} are the steady bitline voltage potential and the complementary bitline voltage potentials for the equilibrium capacitance charge sharing; C_{pg} and C_{bL} are the PMOSFET (21/22) gate capacitance for the selected 4T SRAM and the bitline/complementary bitline capacitance. Since the voltage potentials at the storage nodes (n3 and n4) after the capacitance charge sharing are lower than the voltage (V_{DD}−the threshold voltage of cell PMOSFET 21/22), both cell PMOSFET devices 21 and 22 are initially turned on to charge the bitline and the complementary bitline to the higher voltage potentials. Without the interference of the leakage currents from the NMOSFET devices 314 and 313 cut off by the NMOSFET device 516 in the sensing circuit 550, the cell PMOSFET 22 with slight less voltage potential at the gate or node n4 is turned on more than the cell PMOSFET 21 with slight larger voltage potential at the gate or node n3 (i.e., Vₙ₃>Vₙ₄) to charge the bitline 321 faster than the complementary bitline 322 for the stored data “1” 4T SRAM cell and vice versa for the stored data “0” 4T SRAM cell. Accordingly the differential voltage potentials between bitline and complementary bitline at the sensing nodes 56 and 55 are thus increasing as the time evolving shown in the fifth row and the sixth row respectively for the stored data “1” and stored data “0” 4T SRAM cells in FIG. 6. When the differential voltage potential between bitline and complementary bitline increases to a significant differential voltage margin ΔV after a time “Dt”, the sensing circuit 550 is then turned on by the voltage signal Sn with voltage potential V_{DD} at node 332 for initializing a sensing process to pull the differential voltage between the bitline and complementary bitline from ΔV to the maximum differential voltage V_{DD} as shown in the fifth row and the sixth row respectively for data “1” and data “0” 4T SRAM cells.

The “Sn” signal with voltage potential V_{DD} at node 332 also turns the tri-state buffer 315 on to send out the cell stored data voltage signal V_{DD} (data “1) to the data out bus-line from the sensed voltage signal V_{SS} at the complementary sensing node 55. Meanwhile the PMOSFET device 312 is turned on by the Sn signal with V_{DD} for accelerating the sensing process to charge the bitline BL 321 to the full high voltage potential V_{DD}. Note that during the sensing process, the cell node n4 (curve 605 in FIG. 6) is refreshed with the ground voltage from the previous floating storage node in data retention period such that the total charges on the gate of PMOSFET device 22 for the capacitance of gate and body (N-type well) can be fully restored by the ground voltage at the gate and the digital supply voltage V_{DD} at the body from the previous floating storage node situation during the data retention period. Thus, the original stored datum in the selected 4T SRAM cell is fully refreshed correctly.

### BRIEF DESCRIPTION OF THE DRAWINGS

For a better understanding of the present invention and to show how it may be carried into effect, reference will now be made to the following drawings, which show the preferred embodiment of the present invention, in which:

FIG. 1 shows the schematic of the conventional 6T-SRAM cell.

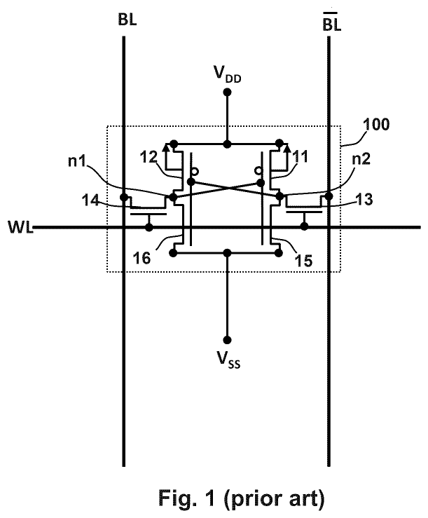

FIG. 2 shows the schematic of the conventional 4T-SRAM cell.

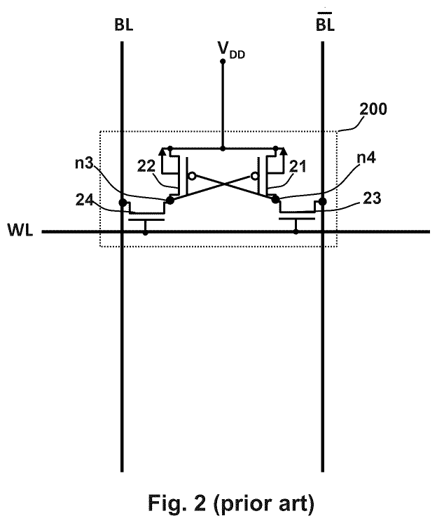

FIG. 3 shows the schematic of the sensing circuit 350 for 4T SRAM cell disclosed in U.S. patent application Ser. No. 18/418,060.

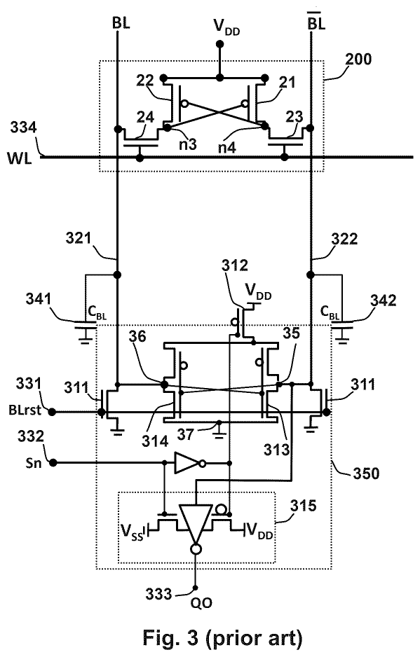

FIG. 4 shows an error reading case for a 4T SRAM cell applied with the previous sensing circuit 350 in FIG. 3.

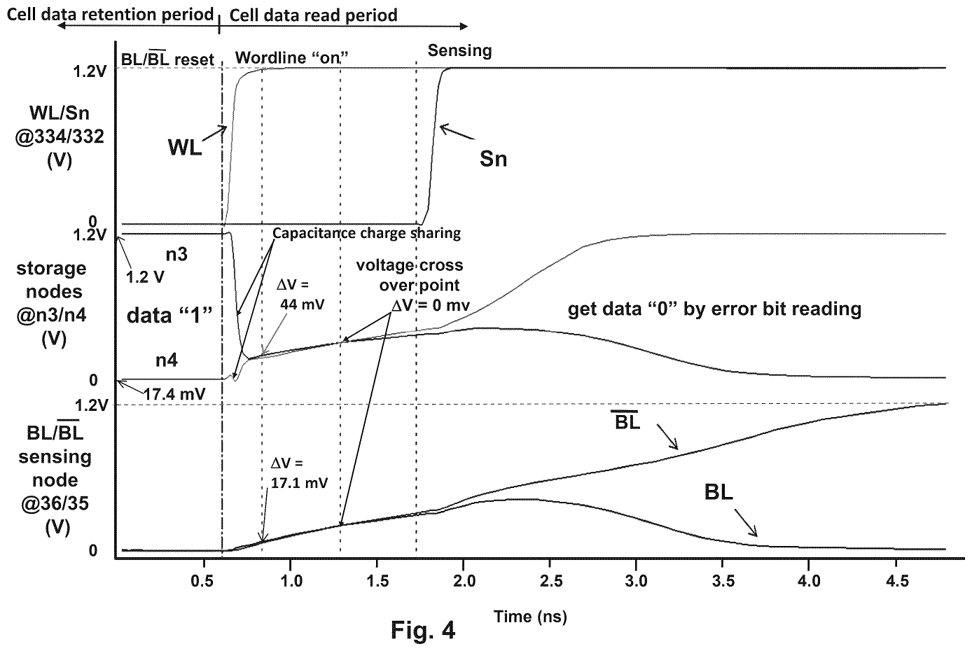

FIG. 5 shows the schematic diagram of the sensing circuit 550 for 4T SRAM cell according to this invention.

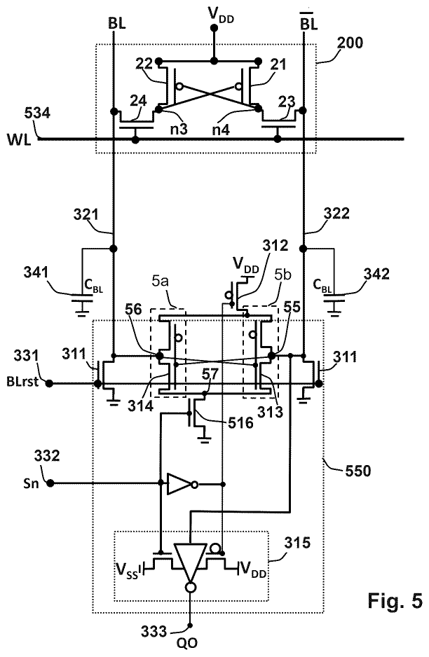

FIG. 6 shows the voltage potential waveform of the read timing sequence for the sensing circuit in FIG. 5 according to this invention.

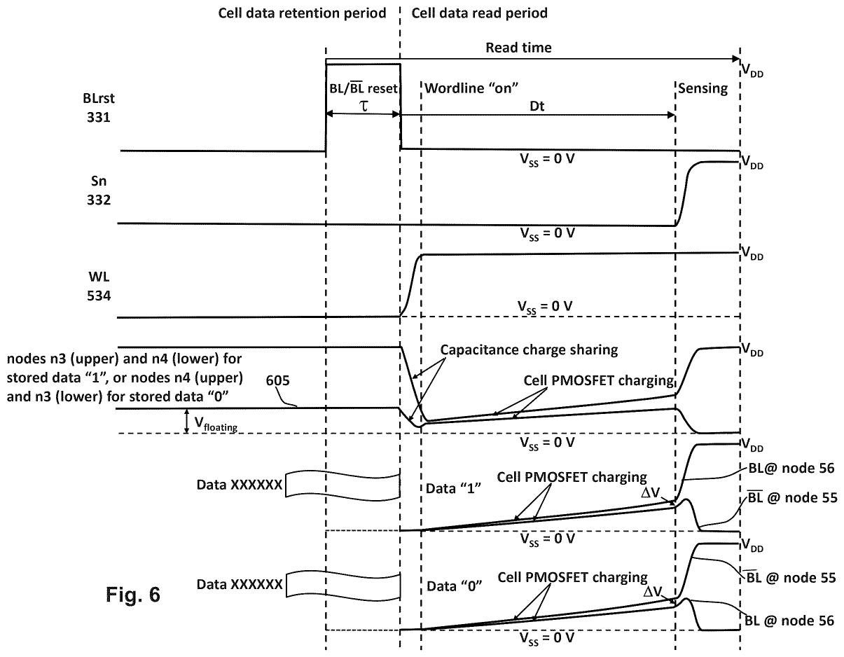

FIG. 7 shows the circuit simulation waveform for reading 4T SRAM cells with extracted parasitic resistance and capacitance parameters for the bitlines and the complementary bitlines according to the memory array layout topology from a 40 nm CMOS process technology provided by a foundry according to one embodiment of the invention.

### DETAILED DESCRIPTION OF THE INVENTION

The following detailed description is meant to be illustrative only and not limiting. It is to be understood that other embodiment may be utilized and various MOSFET devices such as FinFET devices, and GAA (Gate All Around) devices may be made without departing from the scope of the present invention. Also, it is to be understood that the methods of embodiment are for the purpose of description and should not be regarded as limiting. Those of ordinary skill in the art will immediately realize that the embodiment of the present invention described herein in the context of methods and schematics are illustrative only and are not intended to be in any way limiting. Other embodiment of the present invention will readily suggest themselves to such skilled persons having the benefits of this disclosure.

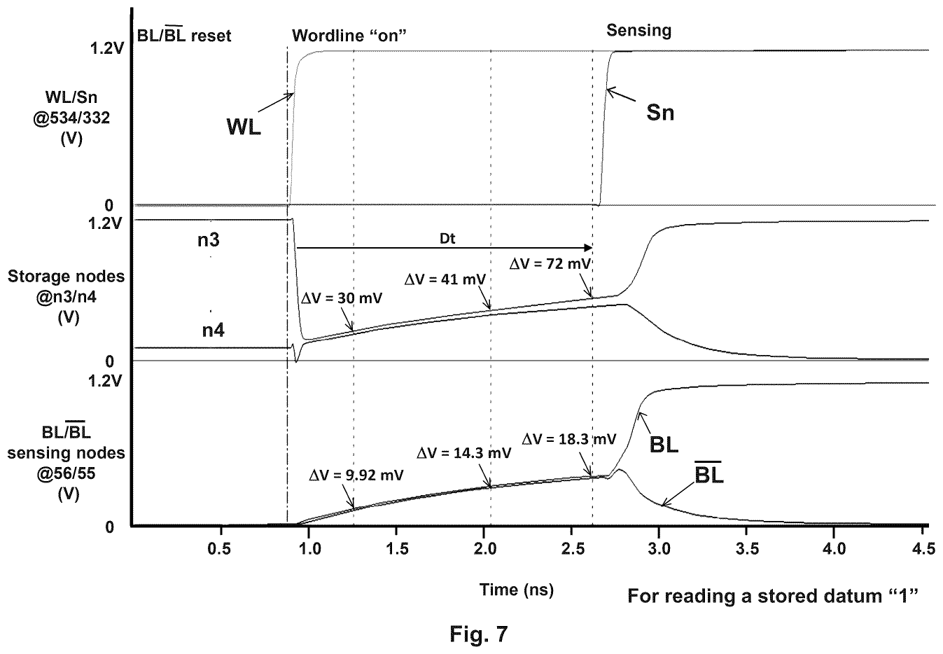

In one embodiment, the sensing circuit 550 for 4T SRAM memory arrays are implemented in a 1 Mb 4T SRAM chip fabricated with foundry's 40 nm CMOS logic process technology. The parasitic resistance and capacitance parameters are extracted from the topological layout of the 4T SRAM memory array. Meanwhile the MOSFET SPICE models from the foundry's PDK (Process Design Kit) are applied for the 4T SRAM write/read operation simulation. The full chip simulation has been performed with different process corners and different temperature environment. A typical simulation read waveform is shown in FIG. 7 for illustrating the working principle of the sensing circuit 550 and sensing scheme for the 4T STAM memory array of the invention. As seen in FIG. 7, the voltage potentials for the storage nodes n3 and n4 of the selected 4T SRAM cell in the second row initially drops to low voltage potentials to turn on both cell PMOSFET device 21 and 22 due to the capacitance charge sharing between cell PMOSFET gate capacitance and the bitline capacitance upon the wordline being turned on with the voltage potential V_{DD}. Both “on” cell PMOSFET devices 22 and 21 are then charging the bitline and the complementary bitline to the higher voltage potentials. As for the case of reading a stored datum “1” in the 4T SRAM cell, the differential voltage potential between the storage nodes n3 and n4 is increasing from 30 mV at 0.58 ns, 41 mV at 0.89 ns, to 72 mV at 1.29 ns after the wordline being turned on. Meanwhile the differential voltage potential between the bitline at the sensing node 56 and the complementary bitline at the sensing node 55 is increasing accordingly from 9.92 mV at 0.58 ns, 14.3 mV at 0.89 ns, to 18.3 mV at 1.29 ns after the wordline being turned on. It can be seen from FIG. 7 that the sensing circuit 550 with the timing sensing scheme can be applied to pull a larger differential voltage between the sensing nodes 55 and 56 with the increasing sensing time Dt, to the maximum differential voltage V_{DD.} In the full chip post simulation, the chip passes for all process corners and different temperature environment.

The aforementioned description of the preferred embodiment of the invention has been presented for purposes of illustration and description. It is not intended to be exhaustive or to limit the invention to the precise form or to exemplary embodiment disclosed. Accordingly, the description should be regarded as illustrative rather than restrictive. The embodiment is chosen and described in order to best explain the principles of the invention and its best mode practical application, thereby to enable persons skilled in the art to understand the invention for various embodiment and with various modifications as are suited to the particular use or implementation contemplated. It is intended that the scope of the invention be defined by the claims appended hereto and their equivalents in which all terms are meant in their broadest reasonable sense unless otherwise indicated. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiment of the invention. It should be appreciated that variations may be made in the embodiment described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A memory device, comprising:
a SRAM cell comprising:
a cross-coupled pair of PMOSFET transistors coupled to a digital voltage rail and two storage nodes; and
two access transistors responsive to a word line and coupled to the two storage nodes and a bit line pair; and
a sensing circuit comprising:
a sensing latch coupled between a first connection node and a second connection node and having two output nodes that are coupled to the bit line pair respectively;
a discharge device responsive to a first control signal and coupled to the two output nodes, the bit line pair and a ground voltage rail; and
a switch device for selectively connecting the second connection node to the ground voltage rail in response to a second control signal.

2. The memory device according to claim 1, wherein the first control signal is activated before the word line is activated, and the word line is activated before the second control signal is activated.

3. The memory device according to claim 2, wherein the discharge device comprises:
a first reset transistor and a second reset transistor responsive to the first control signal, wherein the first reset transistor is coupled to one of the two output nodes, one of the bit line pair and the ground voltage rail, and wherein the second reset transistor is coupled to the other output node of the two output nodes, the other bit line of the bit line pair and the ground voltage rail.

4. The memory device according to claim 2, wherein when the word line is activated, due to charge sharing between gate capacitance of the cross-coupled pair of PMOSFET transistors and capacitance of the bit line pair at the two storage nodes, voltages at the two storage nodes drop below (V_{DD}-Vₜₕₚ) to cause the cross-coupled pair of PMOSFET transistors to be turned on to charge the bit line pair so that a differential voltage between the bit line pair increases as the time elapses, where Vₜₕₚ denotes a threshold voltage of the cross-coupled pair of PMOSFET transistors, and the digital voltage rail carries a supply voltage (V_{DD}).

5. The memory device according to claim 2, wherein before the second control signal is activated, the switch device is turned off to cut channel leakage current paths of NMOSFET transistors in the sensing latch to the ground voltage rail.

6. The memory device according to claim 2, wherein the sensing circuit further comprises:
an accelerating transistor responsive to the second control signal for selectively coupling the digital voltage rail to the first connection node.

7. The memory device according to claim 6, wherein when the second control signal is activated, the switch device, the accelerating transistor and the sensing latch are turned on so that a differential voltage between the bit line pair is pulled to a supply voltage carried by the digital voltage rail.

8. The memory device according to claim 1, wherein the sensing circuit further comprises:
a tri-state buffer having a data input node coupled to one of the two output nodes for selectively outputting a data bit based on a voltage at the one of the two output nodes in response to the second control signal.

9. The memory device according to claim 1, wherein the switch device is a NMOSFET transistor whose gate electrode receives the second control signal.

10. A method of reading a data bit from a SRAM cell in a memory device comprising a sensing circuit, wherein the SRAM cell comprises a cross-coupled pair of PMOSFET transistors and two access transistors, the cross-coupled pair of PMOSFET transistors being coupled to a digital voltage rail and two storage nodes, the two access transistors being responsive to form a word line and coupled to the two storage nodes and a bit line pair, wherein the sensing circuit comprises a switch device, a sensing latch and a discharge device, the sensing latch being coupled between a first connection node and a second connection node and having two output nodes that are coupled to the bit line pair respectively, wherein the discharge device is coupled to the two output nodes, the bit line pair and the ground voltage rail, and the switch device is coupled between the second connection node and the ground voltage rail, the method comprising the steps of:
(1) discharging the bit line pair to a ground voltage by activating the discharge device;
(2) turning off the switch device;
(3) activating the word line to cause voltages at the two storage nodes to drop close to the ground voltage and then cause the bit line pair to be charged after the steps of (1) and (2); and
(4) activating the switch device and the sensing latch to pull a differential voltage between the bit line pair to a supply voltage (V_{DD}) carried by the digital voltage rail in a sensing period after the step of (3).

11. The method according to claim 10, wherein the step of (3) comprises:
activating the word line to cause voltages at the two storage nodes to drop close to the ground voltage due to charge sharing between gate capacitance of the cross-coupled pair of PMOSFET transistors and capacitance of the bit line pair at the two storage nodes; and
when the voltages at the two storage nodes drop below (V_{DD} Vₜₕₚ), causing the cross-coupled pair of PMOSFET transistors to be turned on to charge the bit line pair so that a differential voltage between the bit line pair increases as the time elapses, where Vₜₕₚ denotes a threshold voltage of the cross-coupled pair of PMOSFET transistors.

12. The method according to claim 10, further comprising:
activating a tri-state buffer to output the data bit based on a voltage at one of the two output nodes in the sensing period after the step of (3);
wherein the sensing circuit further comprises the tri-state buffer having a data input node coupled to the one of the two output nodes.

13. The method according to claim 10, wherein the step of (4) comprises:
activating an accelerating transistor to couple the digital voltage rail to the first connection node to charge one of the bit line pair to the supply voltage in the sensing period after the step of (3);
wherein the accelerating transistor is coupled between the digital voltage rail and the first connection node.

14. The method according to claim 10, wherein the switch device is a NMOSFET transistor.
